(19) United States
(12) Patent Application Publication
(10) Pub. No.: US 2005/0000438 A1
(43) Pub. Date: Jan. 6, 2005

(54) Apparatus and method for fabrication of nanostructures using multiple prongs of radiating energy

(76) Inventors: Brian Y. Lim, Santa Barbara, CA (US); Thomas W. Tombler JR., Santa Barbara, CA (US); Jon W. Lai, Santa Barbara, CA (US)

Correspondence Address: C George Yu, 12707 High Bluff DRive, Second Floor PMB 2008, San Diego, CA, 92130, US

(21) Appl. No.: 10/613,513

(22) Filed: Jul. 3, 2003

(51) Int. Cl. C23C 16/00; B05D 3/00; C23C 8/00

(52) U.S. Cl. 118/722; 427/532; 427/554; 427/248.1

(57) ABSTRACT

In one embodiment, an apparatus for fabricating nanostructure-based devices on a workpiece includes: a stage for supporting a workpiece, a radiating-energy source, and a feedstock delivery system. The workpiece has catalyst deposited thereon. The workpiece includes multiple work regions (e.g., dies). The feedstock delivery system is for delivery of feedstock gas to said catalyst. The feedstock delivery system is configured to directly heat catalyst on at least one die via simultaneously emitted multiple prongs of radiating energy. Preferably, the feedstock delivery system includes a feedstock heating system that is configured to heat the feedstock gas not merely by any global heating of a chamber containing the work region or any direct excitation of gas over the work region by the radiating energy.

### TECHNICAL FIELD

The present invention relates to apparatuses or methods for the fabrication of nanostructures. The present invention is especially suited for fabrication of nanostructures on substrates using chemical vapor deposition (CVD), with catalyst and heating, especially in a controlled and high-throughput manner.

### BACKGROUND

Nanotubes, nanowires, and other nanostructures are fascinating materials due to their size, which are on the order of below 1 nm to 100 nm and their unique electrical and physical properties. They have been shown to function as transistors, sensors, field emission sources, diodes, quantum wires, resonators and many other devices. Various methods of synthesis of nanostructures are known.

Earlier-developed methods generally synthesize bulk nanostructured materials or conglomerations of nanostructures (e.g. using laser ablation or arc-discharge). More recently, methods have been investigated that directly synthesize nanostructures on a desired substrate. For example, U.S. Pat. No. 6,346,189, entitled “Carbon nanotube structures made using catalyst islands”, discloses a method in which carbon nanotubes are directly grown on substrates in known locations through patterned catalyst deposition and the CVD method. Existing methods for fabricating nanotubes, nanowires, and other nanostructures generally suffer from very low throughput and efficiency.

For example, consider a method to increase throughput by CVD synthesis of carbon nanotubes on the wafer scale such as described in Franklin, Nathan R. et al. “Patterned Growth of Single Walled Carbon Nanotubes on Full 4″ Wafers”, Appl. Phys. Lett. 79 (2001), 4571-4573. In the discussed method, catalyst is deposited on a 4-inch silicon wafer, which is placed in a large CVD system for nanotube synthesis. Unfortunately, the end product from this method is not uniform throughout the entire wafer due to non-uniform local environments (e.g. temperature and feedstock gas concentration) throughout different areas on the wafer. This method is also a “hit or miss” technique, in which the entire workpiece (substrate) is exposed to the synthesis conditions all at once.

A different and non-global approach is described in two articles: Alexandrescu, R. et al. “Synthesis of Carbon Nanotubes by CO₂-Laser-Assisted Chemical Vapor Deposition”, Infrared Phys. Technol. 44 (2003), 43-50 (hereinafter, Alexandrescu 2003); and Rohmund, F. et al. “Carbon Nanotube Films Grown by Laser-Assisted Chemical Vapor Deposition”, J. Vac. Sci. Technol. B 20 (2002), 802-811 (hereinafter, Rohmund 2002). In the approach described by these articles, a single CO₂ laser is used to locally irradiate (heat) an area on a substrate in the presence of catalytic species and hydrocarbon gas. The laser heats the substrate. The laser also heats the gas through use of C₂H₄, included within the gas, which absorbs some of the CO₂ laser radiation and heats other, non-absorbant gases within the gas by collisional energy exchange. This technique produces multi-walled carbon nanotube films of varying yields and defect densities, as well as occasional single-walled carbon nanotubes. Unfortunately, a drawback of this approach is that the yield and quality are not well controlled. The nanotube synthesis is not uniform, and, again, this approach is questionable for device reproducibility and sufficient throughput, especially if desired for use in high-volume production.

### SUMMARY OF THE INVENTION

What is needed are systems and methods for manufacture of nanometer scaled devices that give improved control over manufacturing conditions, and systems and methods that are capable of high production throughput.

According to one embodiment of the present invention, an apparatus for fabricating nanostructure-based devices on workpieces includes: a stage for supporting a workpiece, a radiating-energy source, and a feedstock delivery system. The workpiece has catalyst thereon. The radiating-energy source is configured to focus radiating energy, from a position spaced apart from said workpiece, toward a work region of the workpiece to directly heat catalyst at the work region, without directly heating catalyst at one or more other work regions of the workpiece. At least the work region is within a chamber. The feedstock delivery system delivers feedstock gas to the catalyst at the work region. The feedstock delivery system includes a feedstock heating system. The feedstock heating system is configured to heat the feedstock gas not merely by any global heating of the chamber or any direct excitation of gas over the work region by the focused radiating energy.

According to another embodiment of the present invention, there is a method for fabricating nanostructure-based devices on a workpiece. The workpiece includes multiple sections, which are referred to in the present paragraph as dies. The method includes the steps of: positioning a die of the workpiece and an energy source in alignment for said energy source to radiate energy onto a surface of the die, the surface being within a chamber; heating feedstock gas to within a predetermined temperature range, and then delivering the heated feedstock gas into the chamber, to flow across the surface of the die; and radiating energy from the energy source externally onto the surface of the die, to thereby heat a catalyst at the surface of the die, wherein a nanostructure is formed at the heated catalyst.

According to another embodiment of the present invention, there is an apparatus for fabricating nanostructure-based devices on a workpiece. The workpiece has catalyst on it. The workpiece includes multiple work sections (e.g., dies). The apparatus includes: a stage for supporting the workpiece, a radiating-energy source configured to directly heat catalyst on at least one die via simultaneously emitted multiple prongs of radiating energy, and a feedstock delivery system for delivery of feedstock gas to the catalyst.

According to another embodiment of the present invention, there is a method for fabricating nanostructure-based devices on a workpiece. The workpiece includes multiple work regions, the method comprises: positioning a work region of the workpiece, and an energy emission system, in alignment for the energy emission system to radiate energy toward a surface of the work region, the surface being within a chamber; flowing feedstock gas to the surface of the work region; and emitting simultaneously multiple beams of radiating energy from the energy emission system externally onto the surface of the die, to thereby heat catalyst disposed on the surface of the die, wherein a nanostructure is formed at the heated catalyst.

The above-mentioned embodiments and other embodiments of the present invention are further made apparent, in the remainder of the present document.

### BRIEF DESCRIPTION OF THE DRAWINGS

In order to more fully describe some embodiments of the present invention, reference is made to the accompanying drawings. These drawings are not to be considered limitations in the scope of the invention, but are merely illustrative.

FIG. 1 contains a schematic perspective view of a workpiece divided into several work regions (e.g, dies) and an enlarged view of one work work region.

FIG. 2 contains a schematic view (e.g., a schematic side view) of an apparatus for fabrication of nanostructure-based devices, according to an embodiment of the present invention.

FIG. 3 contains a schematic view (e.g., a schematic top view) of a feedstock gas delivery nozzle and a work work region, and the ability to adjust their relative rotational position.

FIG. 4 contains a schematic flowchart of a method for fabricating nanostructure-based devices on workpieces, according to one embodiment of the present invention.

FIG. 5 contains a schematic flowchart of a method for fabricating nanostructure-based devices on workpieces, according to one embodiment of the present invention.

### DETAILED DESCRIPTION OF SPECIFIC EMBODIMENTS

The description above and below and the drawings of the present document refer to examples of currently preferred embodiments of the present invention and also describe some exemplary optional features and/or alternative embodiments. It will be understood that the embodiments referred to are for the purpose of illustration and are not intended to limit the invention specifically to those embodiments. For example, preferred features are, in general, not to be interpreted as necessary features. On the contrary, the invention is intended to cover alternatives, variations, modifications and equivalents and anything that is included within the spirit and scope of the invention. To mention just one example, although the drawings show a horizontal stage, other embodiments are possible—for example, an embodiment in which a stage is oriented vertically, or in any other orientation.

Embodiments of the present invention may include any features described in U.S. patent application Ser. No. ______, filed on the same day as the present patent application, entitled “Apparatus and Method for Fabrication of Nanostructures Using Decoupled Heating of Constituents”, attorney docket number ATO-002.00, which is hereby incorporated by reference in its entirety for all purposes.

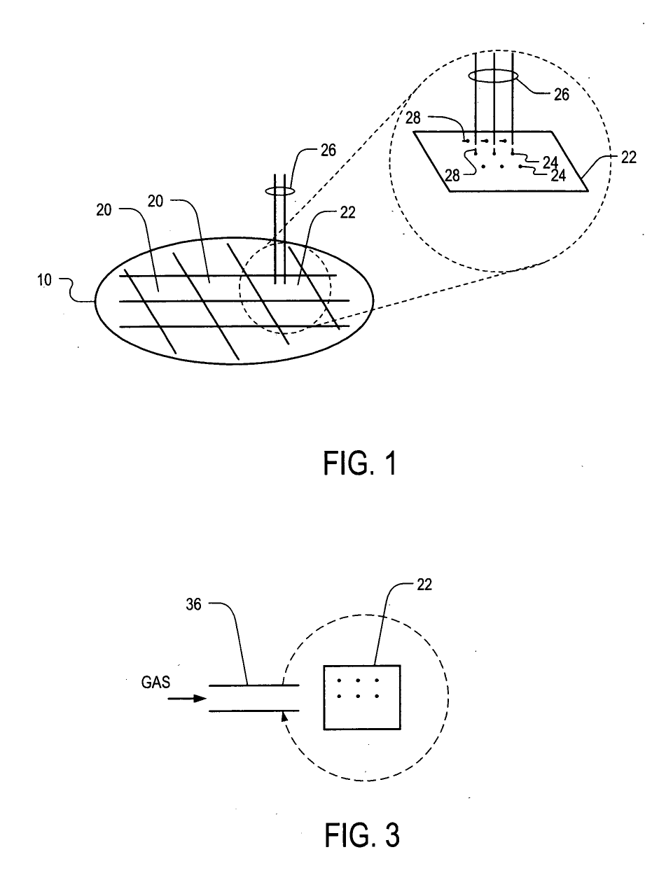

FIG. 1 contains a schematic perspective view of a workpiece 10 (e.g., substrate) divided into several work regions 20 (e.g, dies) and an enlarged view of one work region 22. The enlarged view of the work region 22 shows deposited (e.g., pre-deposited) catalyst 24 (e.g., catalytic species) which are irradiated by focused radiating energy 26 (e.g., laser) to heat the catalyst 24. The heated catalyst is in the presence of gas precursors to nanostructures. By chemical vapor deposition (CVD), nanostructures 28, e.g., nanotubes or nanowires, e.g., carbon nanostructures, are formed at the catalyst 24.

As will be further seen, embodiments of the present invention are especially suitable for exerting precise control over fabrication conditions, even for high-volume processing, even of large-scale workpieces, e.g., 300 mm wafers or larger wafers, e.g., silicon wafers or the like or other wafers suitable or desired for use as substrates.

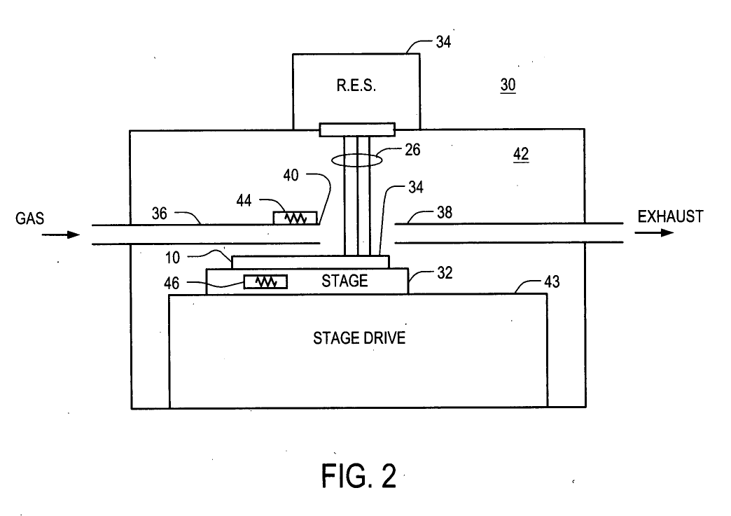

FIG. 2 contains a schematic view (e.g., a schematic side view) of an apparatus 30 for fabrication of nanostructure-based devices, according to one embodiment of the present invention that combines features from multiple other embodiments of the present invention. Of course, the schematic view of FIG. 2, and all other schematic views in the present document, are not to scale. The apparatus 30 is preferably for use as a CVD apparatus.

The apparatus 30 includes a stage 32 for supporting a workpiece 10. The workpiece 10 has catalyst (e.g., iron or gold nanoparticles, or the like, or others) disposed (e.g., deposited) on it. The workpiece 10 includes multiple work regions (e.g., dies) upon it (see FIG. 1). The apparatus 30 also includes a radiating-energy source (RES) 34 that is configured to focus radiating energy 26 toward a work region 22 of the workpiece 10 to directly heat catalyst at the work region 22, without directly heating catalyst at at least some other work regions of the workpiece. The radiating energy is preferably laser, but may be another focusable radiating energy, e.g., acoustic, radio frequency, infrared, microwave, or the like. The apparatus 30 further includes a feedstock delivery system that delivers feedstock gas (e.g., methane, metal vapors, or the like) to the catalyst at the work region 22. Of the feedstock delivery system, gas input guide 36 (e.g., tubing) and gas exhaust guide 38 (e.g., tubing) are shown. The gas input guide includes a nozzle 40 from which feedstock gas is flowed. At least the nozzle 40 is preferably variably positionable in translation, in rotation, or in both, relative to other parts of the apparatus 30. In general, the apparatus 30 includes, or exists at least partially within, walls that define a chamber 42. At least the work region 22 is preferably within the chamber 42. Pressure within the chamber may be at or near atmospheric pressure or lowered to vacuum levels, depending on the particular processing requirements for the particular nanostructures being fabricated. Preferably, temperature sensor(s) (e.g., optical pyrometer(s) or other type(s)) (not shown) give feedback on the temperature of the catalyst that is heated by the focused radiating energy 26, for precise control of heating of the catalyst, e.g., to maintain catalyst temperature to within a predetermined range.

The apparatus 30 preferably further includes a stage drive 43 that can adjust position of the workpiece 10 relative to the radiating-energy source 34. The stage drive 43 can selectively present any of different work regions of the workpiece 10 for irradiation, with other work regions thereby not presented for irradiation. Thus, one work region can be individually processed, followed by a next work region, and so forth. Uniformity, reproducibility, and reliability of the integrated nanostructures is enhanced by working on only one work region at a time.

Preferably, the stage drive 43 can translate the workpiece, as well as rotate the workpiece. Preferably, the apparatus 30 further includes, or is interfaced with, an automated workpiece exchange system (not specifically shown in FIG. 2). Preferably, the workpiece exchange system and the stage drive 43 are fully automated (e.g., motor or hydraulic driven, or the like) and computer controlled. The stage drive 43 can be implemented in various ways. For example, a stage drive 43 can be implemented as shown in U.S. Pat. No. 6,366,308, entitled “Laser thermal processing apparatus and method”, which is hereby incorporated by reference in its entirety for all purposes.

According to one embodiment of the present invention, a CVD apparatus decouples the temperature and heating of the catalyst, workpiece, and feedstock gases, to gain greater control over nanostructure synthesis, to achieve high uniformity, and limit unwanted heating effects. Features of this embodiment of the present invention are shown in FIG. 2. In this embodiment, the radiating-energy source 34 has predominant control over heating of the catalyst to the desired reaction temperature. In this embodiment, a feedstock heating system 44 is configured to heat feedstock gas not merely by any direct excitation of gas over the work region 22 by the focused radiating energy 26 or any global heating of the chamber 42. Great control over preheating of the feedstock gases before exposure is obtained, and better control of reactivity is therefore obtained. For example, the feedstock heating system 44 may include a resistive heater or other heater at or near a nozzle 40 from which the feedstock gases exit the gas input guide 36 toward the catalyst at the work region 22. For example, the distance between the resistive heater and the nozzle 40 can be less than the diameter of the workpiece 10. Preferably, a temperature sensor (e.g., a thermocouple or other type, e.g., at the nozzle 40) (not shown) gives feedback, for precise control of the amount of heating, to regulate heating of the feedstock gases to within a predetermined temperature range that is appropriate for the particular nanostructure being fabricated. As an alternative or supplement to the resistive heater, the feedstock heating system 44 may include a radiating-energy heating system that does not rely on direct excitation of gas over the work region 22. For example, the radiating-energy heating system may use radiating-energy to heat feedstock gases prior to their release from the nozzle 40. The feedstock heating system 44 may alternatively include any other type of gas-heating mechanism. In this embodiment, there is a preferred additional temperature control unit 46 that heats the stage 32, in order to directly heat the workpiece 10, independently of any heating due to the focused radiating energy 26. By raising the workpiece 10 to a higher baseline temperature, less power is needed by the focused radiating energy 26 to achieve desired reaction temperature in the catalyst at the work region 22. Preferably, a temperature sensor (e.g., a thermocouple or other type) (not shown) gives feedback, for precise control of the amount of heating of the workpiece 10, e.g., to maintain workpiece temperature to within a predetermined range. The temperature control unit preferably also includes a cooler, for use to reduce the baseline temperature of the workpiece, or certain portions of the workpiece, to protect temperature-sensitive areas of the workpiece from overheating during processing, e.g., during processing involving other areas of the workpiece. Additionally or alternatively, heat sinks can be fabricated on the workpiece near temperature-sensitive areas, or nanostructures can be fabricated only a safe distance from temperature-sensitive portions of the workpiece. This embodiment of the present invention may optionally be supplemented with any other features shown in FIG. 2 or shown or discussed elsewhere in the present document, unless context demands otherwise.

According to one embodiment of the present invention, a CVD apparatus includes a radiating-energy source 34 that simultaneously emits multiple prongs of energy (e.g., multiple laser beams) as the focused radiating energy 26. Features of this embodiment of the present invention are shown schematically in FIG. 2, in which three vertical laser beams are used schematically to indicate N multiple prongs of energy as the focused radiating energy 26, where N can be at least 10, or at least 50, or at least 100, and the beams are not necessarily parallel to one another or perpendicular to the workpiece. Multiple prongs of energy simultaneously heat multiple catalyst loci (e.g., catalyst islands) on the work region 22—for example, in a pinpoint or otherwise noncontiguous manner—e.g., without irradiating an entire circle, that includes the multiple catalyst islands on the surface of the work region 22, with as much energy as received at the catalyst islands. For example, the radiating-energy source 34 may be configured to emit more than 10, or more than 50, or more than 100 laser beams. This embodiment of the present invention may optionally be supplemented with any other features shown in FIG. 2 or shown or discussed elsewhere in the present document, unless context demands otherwise.

The apparatus 30 optionally further includes an adjustable electric field generator and/or an adjustable magnetic field generator for use in affecting and controlling direction of nanostructure growth. Optionally, the feedstock gas input guide 36 (and preferably also the gas exhaust guide 38) are configured to be adjustable in position and also in direction of flow, relative to at least the workpiece 10, and preferably relative to the radiating-energy source 34 as well. Adjustment in position may include orthogonal distance (e.g., “Z direction”) to the surface of the work region 22. Adjustment in position may further include positional adjustment in two orthogonal dimensions (e.g., “X and Y directions”) in the plane of the work region 22. The adjustment may be performed by an automatic drive (not shown) that translates (e.g., in X, Y, and Z directions) the nozzle 40 (and preferably also a portion of the gas exhaust guide 38) relative to other parts of the apparatus 30. Preferably, the automatic drive is fully computer-controlled.

The processing of one work region can proceed either in one period, or in multiple periods. For example, the processing in multiple periods may differ in their parameters, including, e.g., radiation intensity and duration profile (e.g., profile as a function of time or of another parameter), gas flow formulation profile, gas flow volume and speed profile, gas heating intensity and duration profile, direct workpiece heating and/or cooling profile, position of catalyst islands (and alignment or positioning of the radiating-energy source), growth directionality influences, horizontal-versus-vertical orientation of the stage, and the like, and any other parameters. For example, in one period, growth of nanostructures can be directed in one direction, and then in another period, growth of nearby nanostructures can be directed in a perpendicular direction, whereby the nanostructures are made to cross one another.

FIG. 3 contains a schematic view (e.g., a schematic top view) of a feedstock gas delivery nozzle and a work work region, and the ability to adjust their relative rotational position. The adjustment may be performed by a computer-controlled automatic drive (not shown) that rotates the nozzle 40 (and preferably also a part of the gas exhaust guide 38) of FIG. 2 relative to other parts of the apparatus 30. The adjustment may alternatively, or additionally, be performed by the stage drive 43, which can rotate the workpiece 10.

In the preferred embodiment, a multiple laser beam setup is used to irradiate (heat) the nanostructure catalytic species to the required reaction temperature during which feedstock gases are delivered through the feedstock gas delivery system. The irradiation of the catalyst on a workpiece is done in work regions (e.g., dies) for local area synthesis, which allows for uniformity and reliability that is not possible when the catalyst on the entire area of the workpiece is exposed all at once. The irradiation of catalyst within the die can be done in a single stage (which may be called a period to avoid confusion with the stage 32) or multiple stages (periods). Irradiation in multiple periods allows for different nanostructures and orientations on the same die. Translation of the workpiece relative to the multiple laser beam source allows for die-to-die synthesis of the nanostructures until the entire workpiece is processed. Preferably, the workpiece exchange and die-to-die movement is fully automated and computer controlled. Any or all of the lasers can also be aligned with beam splitters to either increase the area or number of beams or to aid in uniform irradiation of the die. In another embodiment, the focused energy source is a focused acoustic, radio frequency, infrared, or microwave source. These focused energy sources would be focused and positioned so that the desired catalyst in the local area (die) to be exposed is irradiatiated (heated) in a single or in multiple stages.

Various embodiments of the present invention are methods for fabricating nanostructure-based devices on workpieces. Many of these methods are especially applicable to the integration of nanostructures into devices, and in particular the methods and apparatus of achieving large scaled fabrication of nanostructure-based electronic and electromechanical devices in a reliable and controlled way. Some method embodiments of the present invention are discussed below. In general, apparatus embodiments of the present invention may be additionally configured, as necessary, to perform the method steps of the present invention. Similarly, method steps discussed below may be performed according to discussion already made above, in connection with apparatus embodiments.

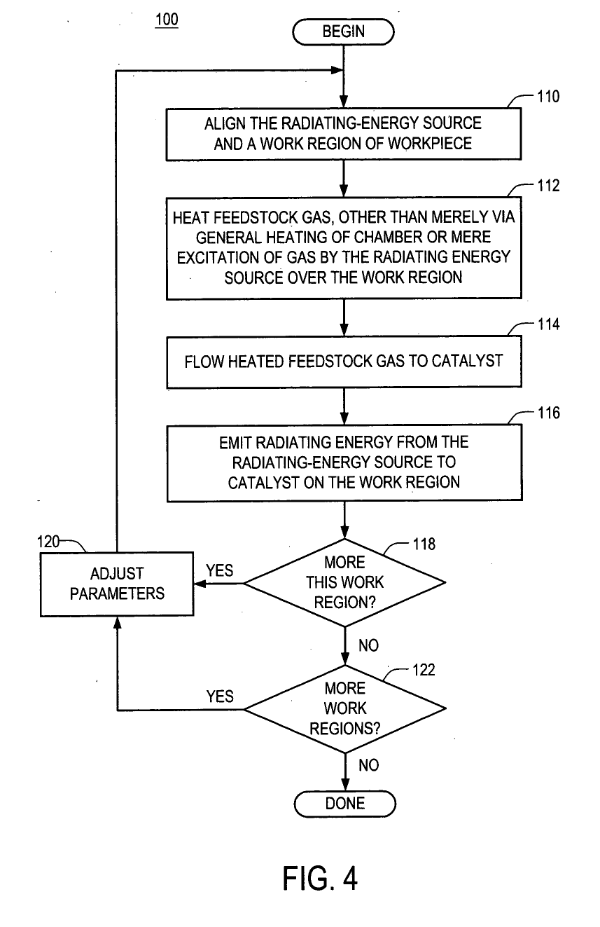

FIG. 4 contains a schematic flowchart of a method 100 for fabricating nanostructure-based devices on workpieces, according to one embodiment of the present invention. In a step 110, a work region of the workpiece is aligned with a radiating-energy source, for the radiating-energy source to be able to irradiate point(s) or area(s) on the work region. In a step 112, feedstock gas is pre-heated (e.g., near the feedstock gas nozzle), other than merely via general heating of chamber or mere excitation of gas by the radiating-energy source over the work region. In a step 114, the heated feedstock gas is flowed to catalyst at the work region. In a step 116, radiating energy is emitted from the radiating-energy source to the heated catalyst on the work region, and to grow nanostructures at the catalyst. The steps 110, 112, 114, and 116 are steps from a stage, which we call a period, of manufacture, in which a set of catalyst islands have been processed according to a set of production parameters to (further) produce growth at the catalyst islands. Optionally, the workpiece may be independently heated or cooled, and directionality of growth may be controlled (e.g., by varying feedstock gas nozzle and/or by use of electric or magnetic fields) with the period of manufacture. In a step 118, it is determined (e.g., preferably by a process computer that runs the production machinery) whether another period of manufacture is desired for the work region. If so, then in a step 120, the parameters for the next period of manufacture are entered (e.g., by automatically looking up the parameters from a computer file and loading them into the apparatus control program) and the next period of manufacture is executed, beginning again with the step 110. If no additional periods of manufacture are desired for the work region, then, in a step 122, it is determined whether other work regions still need to be processed. If so, in the step 120, parameters for a next work region are set up, and the steps 110, 112, 114, 116, 118 are repeated for the (first) period of manufacture for the next work region.

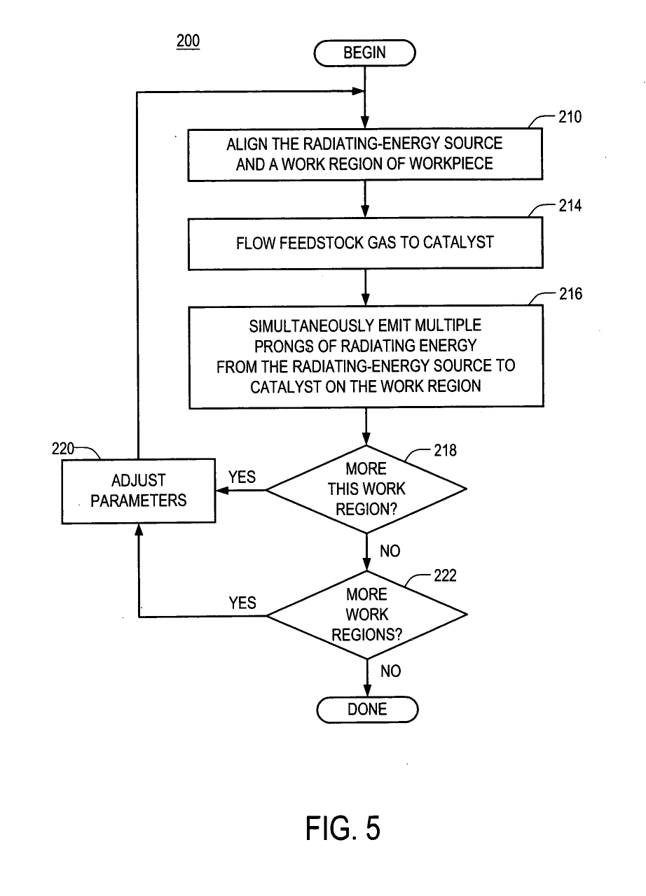

FIG. 5 contains a schematic flowchart of a method 200 for fabricating nanostructure-based devices on workpieces, according to one embodiment of the present invention. A step 210 is similar to the step 110 of FIG. 4. In a step 214, feedstock gas is flowed to catalyst at the work region. In a step 216, multiple prongs of radiating energy are simultaneously emitted from the radiating-energy source to the heated catalyst on the work region. For example, at least 10, or at least 50, or at least 100 lasers are emitted to points on the work region. Steps 218, 220, and 222 are similar to the steps 118, 120, and 122 of FIG. 4. Furthermore, an additional embodiment of the method 100 of FIG. 4 may be formed by replacing the step 116 of FIG. 4 with the step 216 of the method 200 of FIG. 5.

Several embodiments of the present invention have been discussed. Many of these methods are especially applicable to the integration of nanostructures into devices, and in particular the methods and apparatus of achieving large scaled fabrication of nanostructure-based electronic and electromechanical devices in a reliable and controlled way. For example, the apparatus and methodology can be used on a workpiece on which conventional electronic devices have already been fabricated, and onto which nanostructure-based electronics are to be integrated. The particular fabrication protocols and parameters to be used may be selected, depending on the particular nanostructures sought to be produced. For example, the feedstock delivery system is compatible with various gas precursors to nanotubes, nanowires, and nanostructures, as well as non-reactive gases and carrier gases. For example, Alexandrescu 2003 and Rohmund 2002 describe particular examples of production of nanostructures; embodiments of the present invention can adapt parameters to replicate the production described in Alexandrescu 2003 and Rohmund 2002, which are hereby incorporated by reference in their entirety for all purposes.

For example, the feedstock delivery system is configured to be compatible with a gas precursor that selected from the set consisting of CH₄, C₂H₄, C₂H₂, CO, Cl₂, O₂, H₂, N₂, NH₃, SiH₄, GeH₄, and vapor or carrier gas containing materials including at least one of C, Si, Ge, Ga, In, Sn, N, Ga, Ag, Au, Mo, Se, Te, As, Zn, Cd, Mg, Cu, Al, B, S, P, Ti, V, Pt, and Pd.

Throughout the description and drawings, example embodiments are given with reference to specific configurations. It will be appreciated by those of ordinary skill in the art that the present invention can be embodied in other specific forms. The scope of the present invention, for the purpose of the present patent document, is not limited merely to the specific example embodiments of the foregoing description, but rather is indicated by the appended claims. All changes that come within the meaning and range of equivalents within the claims are to be considered as being embraced within the spirit and scope of the claims.

1. An apparatus for fabricating nanostructure-based devices on a workpiece, the apparatus comprising:
a stage for supporting a workpiece, said workpiece having catalyst deposited thereon, said workpiece including multiple work regions, said multiple work regions hereinafter referred to as dies;
a radiating-energy source configured to directly heat catalyst on at least one die via simultaneously emitted multiple prongs of radiating energy; and
a feedstock delivery system for delivery of feedstock gas to said catalyst.

2. An apparatus according to claim 1, wherein said radiating-energy source is a laser source, and said multiple prongs are multiple laser beams.

3. An apparatus according to claim 2, wherein said multiple laser beams comprise a type selected from the set consisting of YAG, excimer, CO₂, argon, helium-neon, ruby, neodymium glass, semiconductor, and free electron.

4. An apparatus according to claim 2, wherein said multiple laser beams originate from a single laser split by at least one beam splitter.

5. An apparatus according to claim 2, wherein said multiple laser beams comprise at least 10 laser beams.

6. An apparatus according to claim 1, wherein said radiating-energy source includes a focused acoustic, focused radio frequency (RF), focused infrared (IR), or focused microwave source.

7. An apparatus according to claim 1, wherein said multiple prongs are positioned and aligned so that all catalyst throughout said die that are desired for seeding growth are irradiated.

8. An apparatus according to claim 1, wherein said multiple prongs are positioned and aligned so that all catalyst throughout said die that are desired for seeding growth are irradiated in multiple irradiating periods, in which a set of islands of catalyst irradiated in a first irradiating period is not identical to a set of islands of catalyst irradiated in a second irradiating period.

9. An apparatus according to claim 1, wherein said multiple prongs are positioned and aligned so that all catalyst throughout said die that are desired for seeding growth are irradiated in multiple irradiating periods, in which each period of said multiple periods uses a different set of fabrication parameters.

10. An apparatus according to claim 1, wherein a plurality of said multiple prongs are produced by a beam splitter from beams that number fewer than said plurality.

11. An apparatus according to claim 1, wherein said feedstock delivery system is positionable at least in distance normal to said die, and in direction of gas flow toward said die.

12. An apparatus according to claim 1, wherein said feedstock delivery system is positionable in X, Y, and Z directions.

13. An apparatus according to claim 1, wherein said stage can be translated or rotated relative to the radiating-energy source, whereby any die among said workpiece is capable of being positioned for exposure to said radiating-energy source.

14. An apparatus according to claim 1, wherein at least a portion of said radiating-energy source can be translated or rotated relative to said stage, whereby said multiple prongs are capable of being selectively positioned for radiating energy onto any given die of a workpiece.

15. An apparatus according to claim 1, wherein said stage includes a stage temperature-control unit for helping to control temperature of a workpiece.

16. An apparatus according to claim 15, wherein said stage temperature-control unit is one that is capable of cooling a workpiece from equilibrium room temperature or a processing temperature to as low as −250 degrees Centigrade.

17. An apparatus according to claim 15, wherein said stage temperature-control unit is one that is capable of heating a workpiece from 0 degrees Centigrade or the equilibrium room temperature to 1200 degrees Centigrade.

18. An apparatus according to claim 1, wherein said apparatus is for fabricating carbon nanostructure-based devices.

19. A method for fabricating nanostructure-based devices on a workpiece, the workpiece including multiple work regions, the method comprising:
positioning a work region of said workpiece, and an energy emission system, in alignment for said energy emission system to radiate energy toward a surface of said work region, said surface being within a chamber;
flowing feedstock gas to said surface of said work region; and
emitting simultaneously multiple prongs of radiating energy from said energy emission system externally onto said surface of said die, to thereby heat catalyst on said surface of said die, wherein a nanostructure is formed at said heated catalyst.

20. A method according to claim 19, wherein said multiple prongs comprise multiple beams of laser.

21. A method according to claim 20, wherein said emitting step comprises using a beam splitter to split one or more laser beams into a greater number of laser beams for emission.

22. A method according to claim 19, wherein said emitting step comprises simultaneously irradiating a first plurality of islands of catalyst on said work region in a first period of operation, then irradiating a second plurality of islands of catalyst on said work region in a second period of operation, wherein fabrication parameters used in said first period of operation differ from fabrication parameters used in said second period of operation.

23. A method according to claim 22, further comprising positioning said feedstock delivery system, using a computer-controlled positioning system, to control said flowing of said feedstock gas, at least in distance normal to said die, and in direction of gas flow toward said die.

24. A method according to claim 19, wherein said positioning step comprises translating or rotating said stage relative to said energy emission system, to position said work region for exposure to said energy emission system.

25. A method according to claim 19, further comprising actively transferring heat to or from said workpiece via said stage, and controlling said transferring using feedback from a temperature sensor affected by temperature of said workpiece.

26. A method according to claim 25, wherein said actively transferring comprises cooling said workpiece from equilibrium room temperature, or from a temperature encountered during said fabricating, to a temperature below a predetermined threshold.

27. A method according to claim 25, wherein said actively transferring comprises heating said workpiece from equilibrium room temperature, or a temperature encountered during said fabricating, to a temperature above a predetermined threshold.

28. A method according to claim 19, wherein said apparatus is for fabricating carbon nanostructure-based devices.
